(19) United States
(12) Patent Application Publication
(10) Pub. No.: US 2023/0324133 A1
(43) Pub. Date: Oct. 12, 2023

(54) LIQUID COOLING JACKET AND COOLING DEVICE

(71) Applicant: Nidec Corporation, Kyoto (JP)

(72) Inventors: Yuta HORI, Kyoto (JP); Kazuhiro NISHIKAWA, Kyoto (JP); Kengo INOUE, Kyoto (JP)

(21) Appl. No.: 18/129,957

(22) Filed: Apr. 3, 2023

(30) Foreign Application Priority Data
Apr. 8, 2022 (JP) 2022-064470

(51) Int. Cl. F28F 13/12; F28F 3/12

(52) U.S. Cl. CPC F28F 13/12; F28F 3/12; H05K 7/20272

(57) ABSTRACT

A liquid cooling jacket includes, with a direction along a direction in which a refrigerant flows being defined as a first direction, and a direction perpendicular or substantially perpendicular to the first direction being defined as a second direction, a refrigerant flow path having a width in the second direction and including a heat radiator on one side in the third direction, a bottom surface portion located on the other side of the refrigerant flow path in the third direction, and protrusions protruding from the bottom surface portion toward one side in the third direction and arranged in the first direction. With one side in the first direction being defined as a downstream side, the protrusions include a convex portion extending in the second direction and protruding toward the other side in the first direction.

### CROSS-REFERENCE TO RELATED APPLICATIONS

The present application claims priority under 35 U.S.C. § 119 to Japanese Patent Application No. 2022-064470, filed on Apr. 8, 2022, the entire contents of which are hereby incorporated herein by reference.

### 1. FIELD OF THE INVENTION

The present disclosure relates to a liquid cooling jacket.

### 2. BACKGROUND

Conventionally, a water jacket used for water cooling is known. A heat radiator is accommodated in the water jacket. The inside of the water jacket serves as a flow path of cooling water, and a heating element is water-cooled via the heat radiator.

In this case, the water jacket is required to reduce a pressure loss in addition to the improvement of cooling performance. When the pressure loss increases, a desired flow rate may not be secured depending on a pump for circulating cooling water. Alternatively, in order to secure a desired flow rate, it is necessary to use a large, expensive pump.

### SUMMARY

A liquid cooling jacket according to a preferred embodiment of the present disclosure includes, with a direction along a direction in which a refrigerant flows being defined as a first direction, a direction perpendicular or substantially perpendicular to the first direction being defined as a second direction, and a direction perpendicular or substantially perpendicular to the first direction and the second direction being defined as a third direction, a refrigerant flow path having a width in the second direction and including a heat radiator on one side in the third direction, a bottom surface portion located on the other side of the refrigerant flow path in the third direction, and protrusions protruding from the bottom surface portion toward one side in the third direction and arranged in the first direction. With one side in the first direction being defined as a downstream side, the protrusion includes a convex portion extending in the second direction and protruding toward the other side in the first direction.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is an exploded perspective view of a cooling device according to an example embodiment of the present disclosure.

FIG. 2 is a side sectional view of the cooling device illustrated in FIG. 1.

FIG. 3 is a plan view of the liquid cooling jacket as viewed from one side in the third direction to the other side in the third direction.

FIG. 4 is a plan view of the liquid cooling jacket on which the placement regions of heating elements are superimposed.

FIG. 5 is a plan view of a liquid cooling jacket according to the first modification of an example embodiment of the present disclosure.

FIG. 6 is a plan view of a liquid cooling jacket according to a second modification of an example embodiment of the present disclosure.

FIG. 7 is a plan view of a liquid cooling jacket according to a third modification of an example embodiment of the present disclosure.

FIG. 8 is a plan view of a liquid cooling jacket according to a fourth modification of an example embodiment of the present disclosure.

FIG. 9 is a plan view of a liquid cooling jacket according to a fifth modification of an example embodiment of the present disclosure.

FIG. 10 is a plan view of a liquid cooling jacket according to a sixth modification of an example embodiment of the present disclosure.

FIG. 11 is a plan view of a liquid cooling jacket according to a seventh modification of an example embodiment of the present disclosure.

FIG. 12 is a plan view of a liquid cooling jacket according to an eighth modification of an example embodiment of the present disclosure.

FIG. 13 is a plan view of a liquid cooling jacket according to a ninth modification of an example embodiment of the present disclosure.

FIG. 14 is a plan view of a liquid cooling jacket according to a tenth modification of an example embodiment of the present disclosure.

### DETAILED DESCRIPTION

Hereinafter, example embodiments of the present disclosure will be described with reference to the drawings.

In the drawings, with the first direction as an X direction, X1 indicates one side in the first direction, and X2 indicates the other side in the first direction. The first direction is a direction along a direction F in which a refrigerant W flows, and the downstream side is indicated by F1 and the upstream side is indicated by F2. The downstream side F1 is one side in the first direction, and the upstream side F2 is the other side in the first direction. With the second direction orthogonal to the first direction as a Y direction, Y1 indicates one side in the second direction, and Y2 indicates the other side in the second direction. With the third direction orthogonal to the first direction and the second direction as a Z direction, Z1 indicates one side in the third direction, and Z2 indicates the other side in the third direction. Note that the above-described “orthogonal” also includes intersection at an angle slightly shifted from 90°. Each of the above-described directions does not limit a direction when a cooling device 1 is incorporated in various devices.

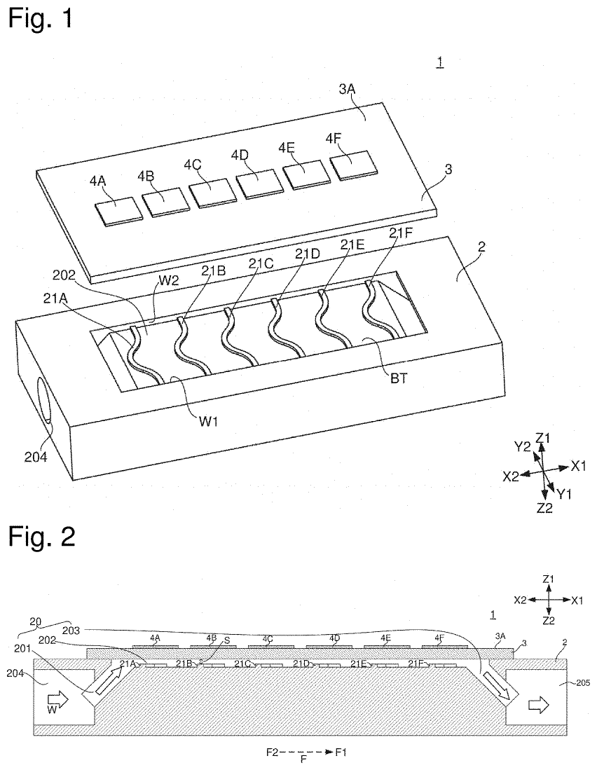

FIG. 1 is an exploded perspective view of the cooling device 1 according to an example embodiment of the present disclosure. FIG. 2 is a side sectional view of the cooling device 1 illustrated in FIG. 1. FIG. 2 is a view when a state in which the cooling device 1 is cut at the center position in the second direction along a cut plane perpendicular to the second direction is viewed from one side in the second direction to the other side in the second direction.

The cooling device 1 includes a liquid cooling jacket 2 and a heat radiator 3. The cooling device 1 is a device that cools a plurality of heating elements 4A, 4B, 4C, 4D, 4E, and 4F (to be referred to as the heating element 4A and the like hereinafter) with a refrigerant W. The refrigerant W is liquid such as water. That is, the cooling device 1 performs liquid cooling such as water cooling. The number of heating elements may be a plural number other than six or may be singular.

The liquid cooling jacket 2 has a rectangular parallelepiped shape having sides extending in the first direction, the second direction, and the third direction. The liquid cooling jacket 2 is, for example, a die-cast product made from a metal such as aluminum. The liquid cooling jacket 2 has a flow path for allowing the refrigerant W to flow therein.

More specifically, the liquid cooling jacket 2 includes a refrigerant flow path 20, an inlet flow path 204, and an outlet flow path 205. The inlet flow path 204 is arranged in the first-direction other end portion of the liquid cooling jacket 2 and has a columnar shape extending in the first direction.

The refrigerant flow path 20 includes a first flow path 201, a second flow path 202, and a third flow path 203. The first flow path 201 has a width in the second direction and is inclined to one side in the first direction and one side in the third direction. The first-direction other end portion of the first flow path 201 is connected to first-direction one end portion of the inlet flow path 204. The second flow path 202 has a width in the second direction and extends in the first direction. The first-direction other end portion of the second flow path 202 is connected to first-direction one end portion of the first flow path 201. The third flow path 203 has a width in the second direction and is inclined to one side in the first direction and the other side in the third direction. First-direction one end portion of the second flow path 202 is connected to the first-direction other end portion of the third flow path 203.

The outlet flow path 205 is arranged in first-direction one end portion of the liquid cooling jacket 2 and has a columnar shape extending in the first direction. First-direction one end portion of the third flow path 203 is connected to the first-direction other end portion of the outlet flow path 205.

In this manner, the refrigerant W flowing into the inlet flow path 204 flows into the first flow path 201 and flows to one side in the first direction and one side in the third direction in the first flow path 201, flows into the second flow path 202 and flows to one side in the first direction in the second flow path 202, flows into the third flow path 203 and flows to one side in the first direction and the other side in the third direction in the third flow path 203, and flows into the outlet flow path 205 and is discharged to the outside of the liquid cooling jacket 2.

Here, the heat radiator 3 is a rectangular parallelepiped flat plate having sides extending in the first direction, the second direction, and the third direction, and has thickness in the third direction. The heat radiator 3 is formed of, for example, a copper alloy. In a state where the heat radiator 3 is not attached to the liquid cooling jacket 2, one side of each of the first flow path 201, the second flow path 202, and the third flow path 203 in the third direction is exposed to the outside. The heat radiator 3 is attached to the liquid cooling jacket 2 by being arranged on one side of the first flow path 201, the second flow path 202, and the third flow path 203 in the third direction. In this manner, one side of each of the first flow path 201, the second flow path 202, and the third flow path 203 in the third direction is not exposed to the outside.

That is, the liquid cooling jacket 2 has a width in the second direction and has the refrigerant flow path 20 in which the heat radiator 3 can be arranged on one side in the third direction.

The heating elements 4A, 4B, 4C, 4D, 4E, and 4F are arranged side by side in this order on the first side in the first direction. The heating element 4A and the like are in direct or indirect contact with a third-direction one side surface 3A of the heat radiator 3. Heat generated from the heating element 4A and the like is transmitted to the refrigerant W flowing through the second flow path 202 via the heat radiator 3, so that the heating element 4A and the like are cooled.

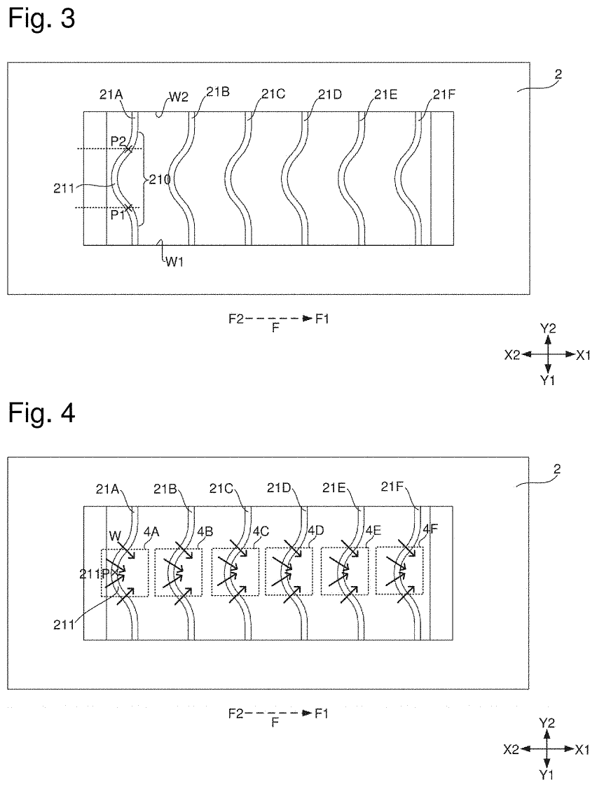

The liquid cooling jacket 2 has a plurality of protrusions 21A, 21B, 21C, 21D, 21E, and 21F (to be referred to as the protrusion 21A and the like hereinafter). In this case, the protrusion 21A and the like will be described in detail with reference to FIG. 3 in addition to FIGS. 1 and 2. FIG. 3 is a plan view of the liquid cooling jacket 2 as viewed from one side in the third direction to the other side in the third direction.

The number of protrusion 21A and the like is six in accordance with the number of heating element 4A and the like. The number of protrusions may be a plurality other than six in accordance with the number of heating elements. The number of protrusions may not necessarily be equal to the number of heating elements.

A wall portion W1 extending in the first direction and the third direction is provided on the first side in the second direction of the second flow path 202. A wall portion W2 expanding in the first direction and the third direction is provided on the other side of the second flow path 202 in the second direction.

The protrusion 21A and the like protrude to one side in the third direction from a bottom surface portion BT arranged on the other side in the third direction of the second flow path 202. That is, the liquid cooling jacket 2 includes a bottom surface portion BT of the refrigerant flow path 20 which is located on the other side in the third direction and the plurality of protrusion 21A and the like protruding from the bottom surface portion BT toward one side in the third direction and arranged in the first direction.

The protrusion 21A and the like have a columnar shape extending in the second direction and are arranged from the wall portion W1 to the wall portion W2. The protrusion 21A and the like have a quadrangular prism shape having a quadrangular cross section as viewed in the second direction.

As illustrated in FIG. 3, the protrusion 21A and the like each have a curved portion 210 that bends toward one side in the first direction after extending toward the other side in the first direction as extending toward the other side in the second direction. That is, the protrusion 21A and the like each have a meandering shape. The curved portion 210 has inflection points P1 and P2. A convex portion 211 is formed between the inflection points P1 and P2. That is, the protrusion 21A and the like each have the convex portion 211 extending in the second direction and protruding to the other side in the first direction.

A gap S in the third direction is formed between each of the protrusion 21A and the like and the heat radiator 3 (see FIG. 2). Therefore, when flowing through the second flow path 202 to one side in the first direction, the refrigerant W passes through each gap S between the protrusion 21A and the like and the heat radiator 3.

FIG. 4 is a plan view of the liquid cooling jacket 2 on which the placement regions of the heating element 4A and the like are superimposed. When passing through each of the gaps S, the refrigerant W tries to pass through a corresponding one of the protrusion 21A and the like at the shortest distance. Therefore, as illustrated in FIG. 4, the flow of the refrigerant W is concentrated on the convex portion 211, and the flow velocity at the convex portion 211 can be improved. Each of the protrusion 21A and the like is disposed at the center position in the second direction, and the heating element 4A and the like are disposed so as to overlap the protrusion 21A and the like. Instead of a decrease in the flow velocity of the refrigerant W in a region other than the second-direction central region in each of the protrusion 21A and the like, the flow velocity of the refrigerant W can be relatively increased in the second-direction central region requiring cooling performance. Therefore, it is possible to efficiently cool the heating element 4A and the like while suppressing an increase in pressure loss.

Further, by disposing the plurality of protrusion 21A and the like, that is, the plurality of convex portions 211 in the first direction, the flow velocity of the refrigerant W can be gradually increased toward the downstream side. On the downstream side, the temperature of the refrigerant W increases due to cooling on the upstream side, and cooling performance is particularly required. Therefore, by improving the flow velocity of the refrigerant W on the downstream side as described above, the cooling performance on the downstream side can be improved.

As illustrated in FIG. 4, a vertex 211P of the convex portion 211 overlaps each of the heating element 4A and the like. That is, the heating element 4A and the like can be disposed on one side in the third direction of the heat radiator 3, and the vertex 211P of the convex portion 211 overlaps each of the placement regions of the heating element 4A and the like when viewed in the third direction. As a result, the region where the flow velocity is high in each of the protrusion 21A and the like overlaps with a corresponding one of the placement regions of the heating element 4A and the like, so that the heating element 4A and the like can be efficiently cooled.

As illustrated in FIG. 4, as viewed in the third direction, the convex portion 211 is disposed over the entire placement region of each of the heating element 4A and the like in the second direction. This can increase the flow velocity in the entire second-direction region of each of the heating element 4A and the like, and the heating element 4A and the like can be cooled more efficiently.

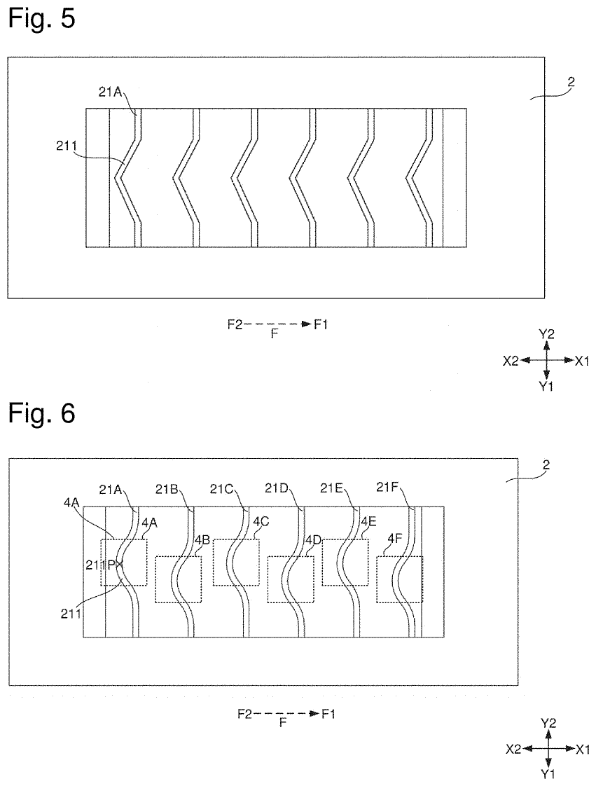

FIG. 5 is a plan view of the liquid cooling jacket 2 according to the first modification. In the liquid cooling jacket 2 illustrated in FIG. 5, the protrusion 21A and the like each have the convex portion 211 that is formed to linearly extend toward one side in the first direction after linearly extending toward the other side in the first direction as extending toward the other side in the second direction. That is, the convex portion 211 is formed in a V shape. The convex portions 211 described above provide the same effect as that of the first example embodiment described above.

However, as in the above example embodiment (see FIG. 3), when the shape of the convex portion 211 has a curvature, the length of the protrusion can be made longer than that of the protrusion having a convex protrusion formed from a linear shape. As a result, the cross-sectional area of the gap S increases, and the flow velocity decreases, so that the pressure loss can be suppressed.

FIG. 6 is a plan view of the liquid cooling jacket 2 according to the second modification. In the liquid cooling jacket 2 illustrated in FIG. 6, the convex portions 211 are alternately arranged on the other side in the second direction and one side in the second direction from the protrusion 21A to the protrusion 21F toward the downstream side. Since the heating element 4A and the like are arranged so as to overlap the vertices 211P of the respective convex portions 211, the heating element 4A and the like are also alternately arranged on the other side in the second direction and one side in the second direction toward the downstream side.

That is, the plurality of convex portions 211 arranged in the first direction include the convex portions 211 at different positions in the second direction. As a result, when the plurality of the heating element 4A and the like arranged in the first direction are arranged at different positions in the second direction, any heating element 4A and the like can be efficiently cooled.

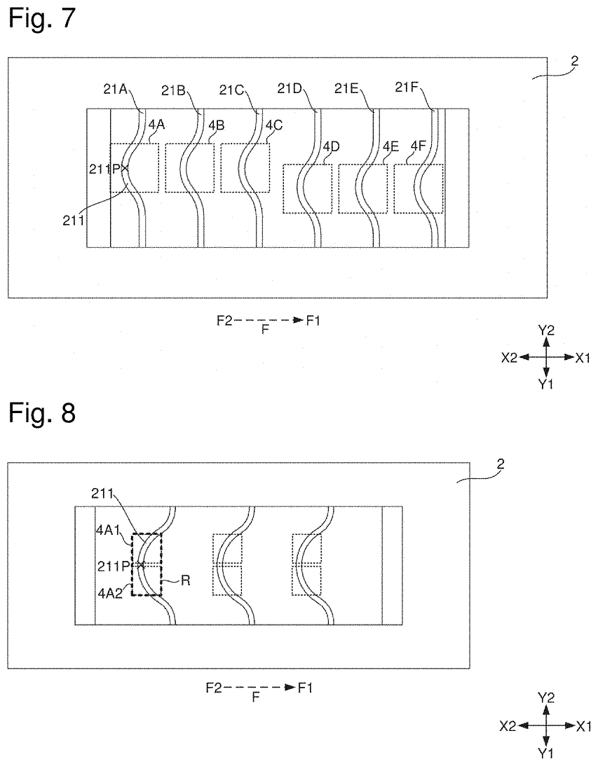

FIG. 7 is a plan view of the liquid cooling jacket 2 according to the third modification. In the liquid cooling jacket 2 illustrated in FIG. 7, the convex portions 211 of the protrusions 21A to 21C are arranged at the same position in the second direction, and the convex portions 211 of the protrusions 21D to 21F are arranged at the same position in the second direction closer to one side in the second direction than the convex portions 211 of the protrusions 21A to 21C. Since the heating element 4A and the like are arranged so as to overlap the vertices 211P of the convex portions 211, the heating elements 4A to 4C are linearly arranged in the first direction, and the heating elements 4D to 4F are linearly arranged in the first direction closer to one side in the second direction than the heating elements 4A to 4C. In the third modification as described above, the plurality of convex portions 211 arranged in the first direction include the convex portions 211 at different positions in the second direction.

FIG. 8 is a plan view of the liquid cooling jacket 2 according to the fourth modification. In the liquid cooling jacket 2 illustrated in FIG. 8, heating elements 4A1 and 4A2 are arranged close to each other in the second direction. The placement region R is one region along the outer edges of the plurality of heating elements 4A1 and 4A2. When viewed in the third direction, the vertex 211P of the convex portion 211 overlaps the placement region R. As a result, the plurality of heating elements 4A1 and 4A2 adjacent in the second direction can be efficiently cooled. Note that a plurality of heating elements other than two heating elements may be arranged close to each other in the second direction.

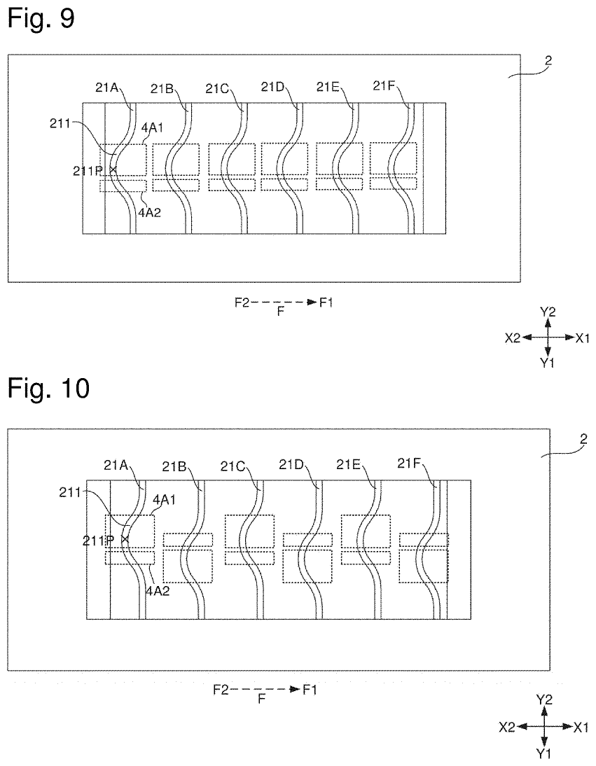

FIG. 9 is a plan view of the liquid cooling jacket 2 according to the fifth modification. As in the fourth modification, in the liquid cooling jacket 2 illustrated in FIG. 9, the heating elements 4A1 and 4A2 are arranged close to each other in the second direction. The heating element 4A1 generates a larger amount of heat than the heating element 4A2. For example, the heating element 4A1 is an insulated gate bipolar transistor (IGBT) chip, and the heating element 4A2 is a diode chip. The heating element 4A1 overlaps the vertex 211P. That is, the heating element 4A1 that generates the largest amount of heat among the plurality of heating elements 4A1 and 4A2 overlaps the vertex 211P as viewed in the third direction. This makes it possible to preferentially cool the heating element 4A1 that generates a large amount of heat. In the configuration illustrated in FIG. 9, since the convex portions 211 are arranged at the same second-direction position across the protrusions 21A to 21F, the plurality of heating elements 4A1 and 4A2 arranged in the first direction are linearly arranged in the first direction.

FIG. 10 is a plan view of the liquid cooling jacket 2 according to the sixth modification. The configuration illustrated in FIG. 10 differs from that of the fifth modification described above in that since the convex portions 211 are alternately arranged in the second direction across the protrusions 21A to 21F, the plurality of heating elements 4A1 and 4A2 arranged in the first direction are alternately arranged in the second direction.

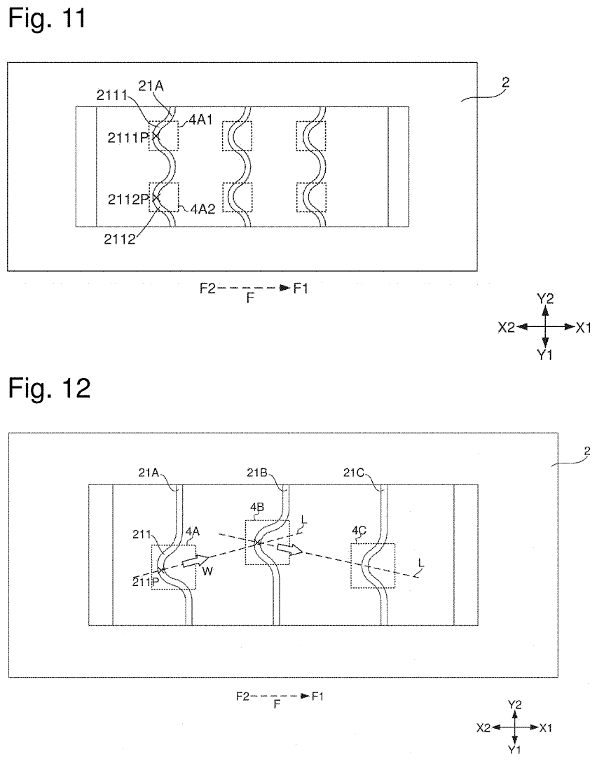

FIG. 11 is a plan view of the liquid cooling jacket 2 according to the seventh modification. In the liquid cooling jacket 2 illustrated in FIG. 11, a plurality of convex portions 2111 and 2112 are arranged in the second direction on the same protrusion 21A or the like. The heating element 4A1 overlaps the vertex 2111P of the convex portion 2111, and the heating element 4A2 overlaps the vertex 2112P of the convex portion 2112. As a result, the plurality of heating elements 4A1 and 4A2 arranged in the second direction can be efficiently cooled. Note that a plurality of convex portions other than two convex portions may be provided on the same protrusion.

FIG. 12 is a plan view of the liquid cooling jacket 2 according to the eighth modification. In the liquid cooling jacket 2 illustrated in FIG. 12, as viewed in the third direction, a normal line L passing through the vertex 211P of the convex portion 211 of the protrusion 21A overlaps the placement region of the heating element 4B adjacent to one side in the first direction. As viewed in the third direction, a normal line L passing through the vertex 211P of the convex portion 211 of the protrusion 21B overlaps the placement region of the heating element 4C adjacent to one side in the first direction. That is, as viewed in the third direction, the normal line L passing through the vertices 211P of the convex portions 211 of the protrusions 21A and 21B overlap the placement region of the heating elements 4B and 4C adjacent to one side in the first direction. The normal line L is inclined with respect to the first direction. As a result, when the heating elements 4A, 4B, and 4C are not linearly arranged along the first direction, the refrigerant W with a high flow rate can be guided toward the next heating element on the downstream side, and the heating elements 4B and 4C can be efficiently cooled.

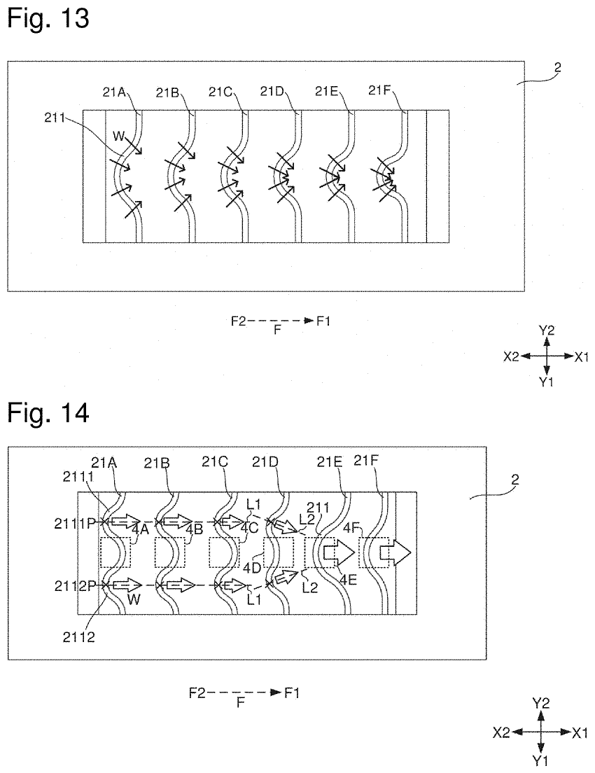

FIG. 13 is a plan view of the liquid cooling jacket 2 according to the ninth modification. In the liquid cooling jacket 2 illustrated in FIG. 13, the curvatures of the convex portions 211 gradually increase from the protrusion 21A to the protrusion 21F. That is, the curvatures of the convex portions 211 increase as the protrusion 21A and the like are arranged on one side in the first direction. This makes it possible to further increase the flow rate on the downstream side where relatively high cooling performance is required and to further improve the cooling performance.

FIG. 14 is a plan view of the liquid cooling jacket 2 according to the 10th modification. Note that FIG. 14 also illustrates the placement regions of the heating element 4A and the like. In the liquid cooling jacket 2 illustrated in FIG. 14, the protrusions 21A to 21D each have two convex portions 2111 and 2112 arranged side by side in the second direction. The convex portions 2111 and 2112 are arranged on both sides of each second-direction central portion in the second direction. The protrusions 21E and 21F each have one convex portion 211. The direction of the normal line L1 passing through the vertices 2111P and 2112P of the convex portions 2111 and 2112 of each of the protrusions 21A to 21C coincides with the first direction. The directions of the normal lines L2 passing through the vertices 2111P and 2112P of the convex portions 2111 and 2112 of the protrusion 21D approach each other toward one side in the first direction. The heating element 4A and the like are linearly arranged in the first direction at the center in the second direction.

That is, the plurality of protrusion 21A and the like arranged in the first direction include the first protrusions 21A, 21B, and 21C each having the two convex portions 2111 and 2112 arranged side by side in the second direction and the second protrusion 21D having the two convex portions 2111 and 2112 arranged side by side in the second direction and arranged closer to one side in the first direction than the first protrusions 21A, 21B, and 21C. The direction of the normal line L1 passing through the vertices of the two convex portions 2111 and 2112 of the first protrusions 21A, 21B, and 21C as viewed in the third direction coincides with the first direction, and the direction of the normal line L2 passing through the vertices of the two convex portions 2111 and 2112 of the second protrusion 21D as viewed in the third direction approaches each other toward one side in the first direction. As a result, the refrigerant W flows at a high flow rate on both sides of each of the heating elements 4A, 4B, 4C, and 4D in the second direction on the upstream side where the cooling performance is relatively unnecessary, and the low-temperature refrigerant W can be joined on the downstream side where the cooling performance is relatively necessary. Therefore, the downstream heating elements 4E and 4F can be efficiently cooled.

As described above, the cooling device 1 according to the present example embodiment includes the liquid cooling jacket 2 and the heat radiator 3 having a flat plate shape that is arranged on one side of the refrigerant flow path 20 in the third direction, spreads in the first direction and the second direction, and has thickness in the third direction. This makes it possible to secure cooling performance while suppressing a pressure loss by protrusions while reducing the cost without providing any fin such as a pin fin for the heat radiator.

The example embodiment of the present disclosure has been described above. The scope of the present disclosure is not limited to the above example embodiment. The present disclosure can be implemented by making various changes to the above example embodiment without departing from the gist of the disclosure. The above example embodiment describes matters that can be optionally combined together, as appropriate, as long as there is no inconsistency.

For example, the heat radiator is not limited to a metal plate, and may be a vapor chamber or a heat pipe.

As described above, a liquid cooling jacket according to one aspect of the present disclosure includes, with a direction along a direction in which a refrigerant flows being defined as a first direction, a direction orthogonal to the first direction being defined as a second direction, and a direction orthogonal to the first direction and the second direction being defined as a third direction, a refrigerant flow path having a width in the second direction and configured to dispose a heat radiator on one side in the third direction, a bottom surface portion located on the other side of the refrigerant flow path in the third direction, and a plurality of protrusions protruding from the bottom surface portion toward the one side in the third direction and arranged in the first direction, wherein with one side in the first direction being defined as a downstream side, the protrusion is configured to extend in the second direction and have a convex portion protruding toward the other side in the first direction.

In the first configuration, a heating element can be disposed on one side of the heat radiator in the third direction.

When viewed in the third direction, the vertex of the convex portion may overlap with the placement region of the heating element (second configuration).

In the second configuration, the convex portion may be disposed over the entire second-direction region of the placement region as viewed in the third direction (third configuration).

In the second configuration, the placement region may be one region along an outer edge of the plurality of heating elements arranged close to each other in the second direction (fourth configuration).

In the fourth configuration, the heating element that generates the largest amount of heat among the plurality of heating elements may overlap the vertex when viewed in the third direction (fifth configuration).

In the second configuration, the plurality of convex portions arranged in the first direction may include the convex portions at different positions in the second direction (sixth configuration).

In the second configuration, the plurality of convex portions may be arranged in the second direction on the same protrusion (seventh configuration).

In the second configuration, when viewed in the third direction, a normal line passing through the vertex of the convex portion on at least one of the protruding portions overlaps the placement region of the heating element adjacent to one side in the first direction, and the normal line may be inclined with respect to the first direction (eighth configuration).

In the first configuration, the shape of the convex portion may have a curvature (ninth configuration).

In the ninth configuration, the curvature may be larger as the protrusion is disposed closer to one side in the first direction (10th configuration).

In the first configuration, a plurality of protrusions arranged in the first direction include a first protrusion having the two convex portions arranged side by side in the second direction, and a second protrusion having the two convex portions arranged side by side in the second direction and arranged closer to one side in the first direction than the first protrusion, the direction of a normal line passing through the vertices of the two convex portions on the first protrusion as viewed in the third direction coincides with the first direction, and the directions of normal lines passing through the vertices of the two convex portions on the second protrusion as viewed in the third direction may approach each other toward one side in the first direction (11th configuration).

A cooling device according to one aspect of the present disclosure includes the liquid cooling jacket having any one of the first to 11th configurations and a flat heat radiator that is disposed on one side of the refrigerant flow path in the third direction, expands in the first direction and the second direction, and has a thickness in the third direction (12th configuration).

The present disclosure can be used for cooling of various heating elements.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A liquid cooling jacket comprising, with a direction along a direction in which a refrigerant flows being defined as a first direction, a direction perpendicular or substantially perpendicular to the first direction being defined as a second direction, and a direction perpendicular or substantially perpendicular to the first direction and the second direction being defined as a third direction:
a refrigerant flow path having a width in the second direction and including a heat radiator on one side in the third direction;
a bottom surface portion located on the other side of the refrigerant flow path in the third direction; and
protrusions protruding from the bottom surface portion toward the one side in the third direction and arranged in the first direction; wherein
with one side in the first direction being defined as a downstream side, the protrusions extend in the second direction and each include a convex portion protruding toward the other side in the first direction.

2. The liquid cooling jacket according to claim 1, wherein
a heater element is located on one side of the heat radiator in the third direction; and
a vertex of the convex portion overlaps a placement region of the heating element when viewed in the third direction.

3. The liquid cooling jacket according to claim 2, wherein the convex portion is provided throughout the placement region in the second direction as viewed in the third direction.

4. The liquid cooling jacket according to claim 2, wherein there are a plurality of the heating elements and the placement region is one region along an outer edge of multiple ones of the plurality of the heating elements arranged adjacent to each other in the second direction.

5. The liquid cooling jacket according to claim 4, wherein a heating element that generates a largest amount of heat among the plurality of heating elements overlaps the vertex as viewed in the third direction.

6. The liquid cooling jacket according to claim 2, wherein the convex portions are arranged in the first direction and include convex portions at different positions in the second direction.

7. The liquid cooling jacket according to claim 2, wherein the convex portions are arranged in the second direction on a same one of the protrusions.

8. The liquid cooling jacket according to claim 2, wherein
when viewed in the third direction, a normal line passing through the vertex of the convex portion on at least one of the protrusions overlaps the placement region of the heating element adjacent to one side in the first direction; and
the normal line is inclined with respect to the first direction.

9. The liquid cooling jacket according to claim 1, wherein a shape of the convex portion includes a curvature.

10. The liquid cooling jacket according to claim 9, wherein the curvature increases as the protrusion becomes closer to one side in the first direction.

11. The liquid cooling jacket according to claim 1, wherein
the protrusions arranged in the first direction include:
a first protrusion including two of the convex portions arranged side by side in the second direction; and
a second protrusion including the two convex portions arranged side by side in the second direction and arranged adjacent to one side in the first direction than the first protrusion;
the direction of a normal line passing through the vertices of the two convex portions on the first protrusion as viewed in the third direction coincides with the first direction; and
the directions of normal lines passing through the vertices of the two convex portions on the second protrusion as viewed in the third direction approaches each other toward one side in the first direction.

12. A cooling device comprising:
the liquid cooling jacket according to claim 1; and
a heat radiator having a flat plate shape and being located on one side of the refrigerant flow path in the third direction, extending in the first direction and the second direction, and having a thickness in the third direction.
